(19) United States
(12) Patent Application Publication
(10) Pub. No.: US 2025/0318351 A1
(43) Pub. Date: Oct. 9, 2025

(54) HYBRID PIXEL STRUCTURE FOR MICROLED APPLICATIONS

(71) Applicant: Applied Materials, Inc., Santa Clara, CA (US)

(72) Inventors: Fabio PIERALISI, Aschaffenburg (DE); Zhiyong LI, Foster City, CA (US); Lisong XU, San Jose, CA (US); Kai DING, Cupertino, CA (US); Hou T. NG, Campbell, CA (US); Uma SRIDHAR, Sunnyvale, CA (US); Mingwei ZHU, San Jose, CA (US); Nag PATIBANDLA, Dublin, CA (US)

(73) Assignee: Applied Materials, Inc., Santa Clara, CA (US)

(21) Appl. No.: 19/171,894

(22) Filed: Apr. 7, 2025

Related U.S. Application Data
(60) Provisional application No. 63/575,495, filed on Apr. 5, 2024.

(51) Int. Cl. H10H 29/856; H01L 25/075; H10H 29/01; H10H 29/24

(52) U.S. Cl. CPC H10H 29/856; H01L 25/0753; H10H 29/0361; H10H 29/0363; H10H 29/24

(57) ABSTRACT

A method of forming a micro light-emitting diode (microLED) array may include forming pixel isolation structures on a sacrificial substrate, and mounting the microLEDs on a separate backplane. The processes that forms the pixel isolation structures, and which may damage the backplane or microLEDs can be separately performed on the sacrificial substrate. The pixel isolation structures can then be attached to the backplane and the sacrificial substrate can be removed. This allows the formation of the pixel isolation structures to be isolated, the microLEDs to be tested early in the process, and the interface between the microLEDs and subsequent layers to be free of adhesive.

### CROSS-REFERENCES TO RELATED APPLICATIONS

This application claims the benefit of priority to U.S. Patent Application No. 63/575,495 filed Apr. 5, 2024, the contents of which are hereby incorporated by reference in their entirety for all purposes.

### TECHNICAL FIELD

The present technology relates to display panels. More specifically, the present technology relates to pixel structures and methods of forming pixel structures for display panels.

### BACKGROUND

Flat panel displays are made possible by pixel structures that produce monochromatic ultraviolet light that is subsequently down-converted into visible light. The generation of ultraviolet light and its down-conversion both generate waste heat. Furthermore, as pixel sizes continue to shrink, and pixel density increases, thermal management within the display panels becomes increasingly challenging. During operation, heat from ultraviolet light sources may raise the operating temperature of the down-conversion material, which may be sensitive to excess heat. Consequently, down-conversion efficiency and device lifetime may be negatively affected.

Thus, there is a need for improved pixel display structures and methods that can be used to produce high quality pixel structures. These and other needs are addressed by the present technology.

### SUMMARY

In some embodiments, a method of forming pixel structures for a microLED array may include forming pixel isolation structures on a first substrate; attaching the pixel isolation structures to a second substrate, where the second substrate may include light sources, and the pixel isolation structures may isolate the light sources from each other; and removing the first substrate from the pixel isolation structures.

In some embodiments, a method of forming pixel structures for a microLED array may include forming pixel isolation structures on a first substrate; attaching the pixel isolation structures to a second substrate such that the first substrate is attached to a first side of the pixel isolation structures, and the second substrate is attached to a second side of the pixel isolation structures; and providing a stimulus that causes the pixel isolation structures to release from the first substrate without causing the pixel isolation structures to release from the second substrate.

In some embodiments, a pixel structure of a microLED array may include a substrate with light sources mounted to the substrate; pixel isolation structures that isolate the light sources from each other, and that are connected to the substrate with a first adhesive layer; and a transparent substrate disposed over the pixel isolation structures and connected to the pixel isolation structures with a second adhesive layer.

In any embodiments, any and all of the following features may be implemented in any combination and without limitation. an inspection or test of the light sources may be performed after attaching the pixel isolation structures to the second substrate and before forming a color-conversion layer over the light sources. A defective light source on the second substrate may be replaced as a result of the inspection or test and before forming the color-conversion layer over the light sources. a first color-conversion layer may be formed within first regions formed by the pixel isolation structures and over a first portion of the light sources, where the first color-conversion layer may include a bluish color; the first color-conversion layer may be cured within the first regions using light from the first portion of the light sources; and any of the first color-conversion layer outside of the first regions may be removed after curing. A second color-conversion layer may be formed within second regions formed by the pixel isolation structures over a second portion of the light sources, where the second color-conversion layer may include a reddish color; the second color-conversion layer may be cured within the second regions using light from the second portion of the light sources; and any of the second color-conversion layer outside of the second regions formed by the pixel isolation structures may be removed after curing. a third color-conversion layer may be formed within third regions formed by the pixel isolation structures over a third portion of the light sources, where the third color-conversion layer may include a reddish color; the third color-conversion layer may be cured within the third regions using light from the third portion of the light sources; and any of the third color-conversion layer outside of the third regions formed by the pixel isolation structures may be removed after curing. a transparent substrate may be attached to the pixel isolation structures in place of the first substrate after the first substrate is removed. Light sources may be mounted to the second substrate and connected by an interconnect of the second substrate, and the first substrate may include a sacrificial substrate that may be nontransparent with respect to light generated by the light sources mounted to the second substrate. A surface of the first substrate may be coated with a first adhesive layer prior to forming the pixel isolation structures on the first substrate, where the pixel isolation structures may be formed such that the first adhesive layer is between the surface of the first substrate and the first side of the pixel isolation structures. The first adhesive layer may include a pressure-sensitive adhesive. The second side of the pixel isolation structures may be attached to the second substrate using a second adhesive layer. The stimulus may include a laser, and the laser may be provided with a focal length that focuses at the first adhesive layer and that does not focus at second adhesive layer. The stimulus may include a laser that emits light at a wavelength, and the wavelength may disrupt the first adhesive layer without disrupting the second adhesive layer. The first adhesive layer may have a melting point that is lower than the second adhesive layer. The stimulus may include a temperature that causes the first adhesive layer to melt without causing the second adhesive layer to melt. The pixel structure may also include a reflective layer that covers sidewalls of the pixel isolation structures, where the reflective layer need not cover a first side of the pixel isolation structures that is connected to the transparent substrate. The pixel structure may also include a reflective layer that covers sidewalls of the pixel isolation structures, where the reflective layer may also cover a first side of the pixel isolation structures that is connected to the substrate The pixel structure may also include a reflective layer that includes a metal material.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A-1B illustrate a method of manufacturing a pixel structure for a microLED array that includes forming the CCL layers directly on the microLEDs, according to some embodiments.

FIGS. 2A-2B illustrate an alternative method of fabricating a pixel structure, according to some embodiments.

FIG. 3 illustrates a flowchart of a method for forming pixel structures for a microLED array, according to some embodiments.

FIGS. 4A-4F illustrate example structures for some of the operations performed in the flowchart of FIG. 3.

FIGS. 5A-5C illustrate example structures for some of the operations performed in the flowchart of FIG. 3 for microLED communication applications.

### DETAILED DESCRIPTION

A method of forming a micro light-emitting diode (microLED) array may include forming pixel isolation structures on a sacrificial substrate, and mounting the microLEDs on a separate backplane. The processes that forms the pixel isolation structures, and which may damage the backplane or microLEDs can be separately performed on the sacrificial substrate. The pixel isolation structures can then be attached to the backplane and the sacrificial substrate can be removed. The color-conversion layers may then be deposited individually and cured using the light from the corresponding microLEDs in display applications. Alternatively, color-conversion layers may be replaced by optically transparent layers or may be omitted entirely in microLED communication applications. A protective cover layer may then be optionally adhered over the pixel isolation structures and the color conversion layers. This allows the formation of the pixel isolation structures to be isolated, the microLEDs to be tested prior to the formation of subsequent layers over the microLEDs, the interface between the microLEDs and the areas above the microLEDs to be free of adhesive.

Micro light-emitting diode (microLED) arrays are emerging as the next generation in flat-panel display technology due in large part to their superior contrast and brightness, faster response times, reduced energy consumption, higher pixel density, and longer lifetime. Optimal performance and efficiency of the optical display may be achieved by using monochrome microLEDs that emit light in the ultraviolet (UV) region. A color-conversion layer (CCL) may be formed over the microLEDs to convert the light emitted by the microLEDs into specific wavelengths of visible light. For example, a CCL formed using quantum dots may convert the microLED radiation into primary colors, such as red, green, and blue. Despite the advantages of microLED displays, the manufacturing processes used to form microLED arrays are still subject to a number of technical problems.

MicroLED arrays are also emerging as the next generation in digital communication technology. MicroLED arrays may include light sources that individually transmit digital data in parallel by turning on and off. These transitions may be received by corresponding photodetectors in another system. Leveraging the fast response times, high efficiency, and compact size of microLEDs, this technology enables precise and reliable optical communication for applications ranging from inter-chip data transfer to optical interconnects in high-performance computing systems. Unlike traditional communication methods, microLEDs can transmit data at very high modulation speeds while maintaining low power consumption, making them ideal for bandwidth-intensive applications.

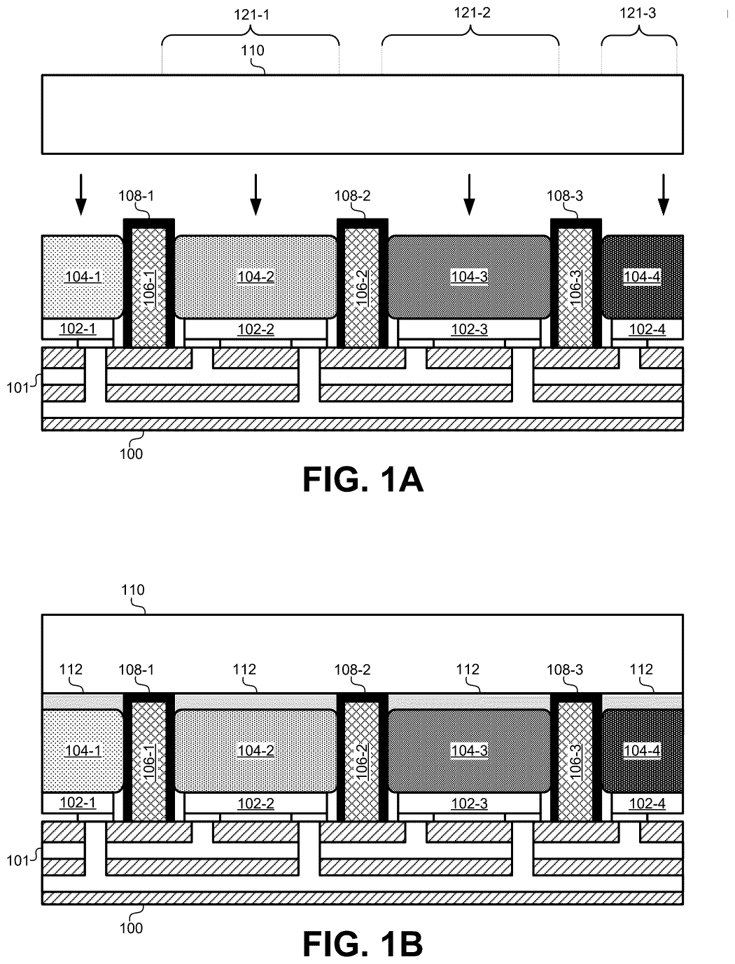

FIGS. 1A-1B illustrate a method of manufacturing a pixel structure 101 for a microLED array that includes forming the CCL layers directly on the microLEDs, according to some embodiments. The materials and descriptions of the various components in the pixel structure 101 of this array are provided only by way of example, and are not meant to be limiting. Furthermore, the materials and techniques described below in relation to FIGS. 1A-1B may also be equally applicable to the other embodiments described further below that may use different assembly methods for the different components.

These figures illustrate a schematic, cross-sectional view of a pixel structure 101 of a display device panel stack according to some embodiments. This pixel structure 101 may also be used in a microLED array for optical communication applications. The pixel structure 101 may be incorporated in a system including control electronics and power systems to facilitate its use as an addressable pixel in an array. The pixel structure 101 may show a partial view of the structures and components being discussed, and may illustrate a view across a cross section of a pixel, which may otherwise include any number of pixel structures to form a pixel array including as many as millions of individually addressable pixels or more. Any aspect of pixel structure 101 may also be incorporated with other display or communication systems.

The pixel structure 101 may include two sections providing complementary functionality, permitting the pixel structure 101 to emit visible light in a broad color spectrum and over a broad range of intensities. As illustrated, the pixel structure 101 may include a first substrate 110 and a second substrate 100. The first substrate 110 may include a covered glass or other transparent substrate that serves to protect the pixel structure 101 and allow light to travel through the first substrate 110. The second substrate 100 may be or include a light source panel, including light sources 102, such as light emitting diodes (LEDs) or microLEDs that are configured to emit light in an ultraviolet range. For example, the light sources 102 may emit in the UV-A range between 315 nm and 400 nm, for example, at or about a wavelength of 400 nm or less, at or about a wavelength of 390 nm or less, at or about a wavelength of 380 nm or less, at or about a wavelength of 370 nm or less, at or about a wavelength of 360 nm or less, at or about a wavelength of 350 nm or less, at or about a wavelength of 340 nm or less, at or about a wavelength of 330 nm or less, at or about a wavelength of 320 nm or less, or less. Similarly, the light sources 102 may emit in the UV-B range between 280 nm and 315 nm, for example, at or about a wavelength of 315 nm or less, at or about a wavelength of 305 nm or less, at or about a wavelength of 295 nm or less, at or about a wavelength of 285 nm or less, or less. Similarly, the light sources 102 may emit in the UV-C range between 100 nm and 280 nm, for example, at or about a wavelength of 280 nm or less, at or about a wavelength of 270 nm or less, at or about a wavelength of 260 nm or less, at or about a wavelength of 250 nm or less, at or about a wavelength of 240 nm or less, or less. The emission wavelength of the light sources 102 may be monochromatic, meaning that each source may emit at a single peak wavelength. The peak wavelength may be the same for the UV light sources 102, such that each of the light sources 102 may produce a substantially equivalent emission spectrum. Alternatively, different light sources 102 may produce a different emission spectrum, for example, in relation to material parameters of other components that are formed between the light sources 102 and the top of the first substrate 110.

To facilitate the individual addressability of the light sources 102, second substrate 100 may be or include a backplane comprising one or interconnect layers 101. The backplane may be or include a multilayer structure, for example, being formed by processes including deposition, etching, and removal forming part of semiconductor fabrication operations. In some embodiments, the backplane of the second substrate 100 may be formed to include including metallized contacts. The contacts may be or include metal thin films, such as those deposited by chemical or physical vapor deposition processes. The contacts may provide electronic communication between the light sources 102 and an array controller and/or a power system, by which the light sources 102 may be individually addressed. Individual addressability of each of the individual light sources 102 may facilitate the functionality of the pixel structure 101 as an emitter of visible light across a broad spectral range, from deep bluish to deep reddish wavelengths.

The pixel structure 101 may include a multilayer structure configured to down-convert UV light into visible light that may reproduce the broad spectral range by combining substantially monochromatic light emitted by multiple sub-pixels. For example, the pixel structure 101 may include, but is not limited to, a first sub-pixel 121-1, a second sub-pixel 121-2, and a third sub-pixel 121-3. The sub-pixels may be configured to down-convert visible light from UV light at or about three or more principle wavelengths within multiple wavelength ranges, such that the pixel structure 101 may emit visible light of an arbitrary color within the broad spectral range. For example, the first sub-pixel 121-1 may be configured to down-convert UV light to emit visible light in a bluish wavelength range, between about 380 nm and 550 nm. Similarly, the second sub-pixel 121-2 may be configured to down-convert UV light to emit visible light in a greenish wavelength range, between about 400 nm and 700 nm. Similarly, the third sub-pixel 121-3 may be configured to down-convert UV light to emit visible light in a reddish wavelength range, between about 425 nm and 700 nm. In some embodiments, the first sub-pixel 121-1 may be configured to emit bluish visible light centered around a peak wavelength at or about 475 nm, the second sub-pixel 121-2 may be configured to emit greenish visible light centered around a peak wavelength at or about 560 nm, and the third sub-pixel 121-3 may be configured to emit reddish visible light centered around a peak wavelength at or about 640 nm. In some embodiments, the sub-pixels 121 may be configured to emit visible light within a relatively narrow wavelength distribution, as measured by a full width at half maximum spectral bandwidth each respective sub-pixel. For example, the full width at half-maximum (FWHM) of each of the sub-pixels 121 may be about 40 nm or less, about 30 nm or less, about 25 nm or less, about 20 nm or less, or less.

To produce visible light in multiple wavelength ranges each sub-pixel may include color-conversion layers 104 (also referred to as “down-conversion layers”) incorporating a material selected to absorb UV light emitted by the light sources 102 and to emit visible light at a longer wavelength. For example, a first color-conversion layer 104-1 may incorporate quantum dots, phosphors, or other materials selected to absorb UV photons and to emit visible photons in the bluish visible wavelength range. Similarly, a second color-conversion layer 104-2 and a third color-conversion layer 104-3 may incorporate such materials to down-convert UV photons into visible photons in the greenish and reddish visible wavelength ranges, respectively. In addition to the color-conversion material, the down-conversion layers 104 may incorporate a transparent matrix within which the color-convertor material may be suspended. For example, in the case of quantum dot color-convertor material, a plurality of quantum dots may be suspended in a transparent matrix. To potentially improve the color-conversion efficiency of the color-conversion layers 104, the color-conversion layers 104 may include a scattering material to reduce through-transmission of UV photons and to increase the fraction of UV photons that interact with the color-convertor material. As an example, the color-conversion layers 104 may incorporate titanium oxide nanoparticles suspended in the transparent matrix, which may act to scatter the incident UV photons and increase interactions between UV photons and the color-convertor material.

The pixel structure 101 may also include layers to condition light before it is emitted and to provide structural support for the pixel structure 101. For example, the pixel structure 101 may include a transparent substrate 110, which may be or include, but is not limited to, glass or plastic, such that the transparent substrate 110 is transparent to visible light. In some embodiments, the transparent substrate 110 may be or include a material that is selectively transparent in the visible wavelength range, but absorbs broadly in the UV range. The transparent substrate 110 may also be referred to as a “cover” or as “cover glass.” In some embodiments, overlying the transparent substrate 110, the pixel structure 101 may include one or more coatings or intermediate layers including color filter layers or UV blocking layers. The color filter layers may be or include materials selected to filter light by wavelength, such that light outside a pre-defined spectral range may be removed prior to emission from the respective sub-pixels 121. For example, a color filter layer may be or include a long-pass filter material, a short-pass filter material, or a band-pass filter material, such that light outside a pre-defined wavelength range may be removed. Materials for the color filter layers may include thermoplastic or other polymeric materials. Additionally or alternatively, the color filter layers may incorporate dichroic filter coatings, such that UV light and light outside the pre-defined wavelength range may be reflected back into the color-conversion layers 104, which may improve the conversion efficiency of the color-conversion layers 104. In some cases, the UV blocking layer may protect the color filter layers by limiting exposure of the constituent materials to UV light transmitted through the color-conversion layers 104 of the sub-pixels 121. For example, a polymeric color filter material may be sensitive to UV light, which may degrade the color filter layer over a period of time. In this way, the UV blocking layer, which may be or include thin films of polymeric materials, borosilicate materials, or other materials selected to block photons with a wavelength of about 400 nm or less.

In some embodiments, the transparent first substrate 110 may have a thickness greater than or about 25 μm and less than or about 1 mm. The thickness of the transparent first substrate 110 may be greater than or about 50 μm, be greater than or about 75 μm, be greater than or about 100 μm, be greater than or about 200 μm, be greater than or about 300 μm, be greater than or about 400 μm, be greater than or about 500 μm, be greater than or about 600 μm, be greater than or about 700 μm, be greater than or about 800 μm, be greater than or about 900 μm, or greater, and less than or about 1 mm.

In some embodiments, the color filter layer may have a thickness greater than or about 1 μm and less than or about 20 μm. The thickness of the color filter layer may be greater than or about 2 μm, greater than or about 3 μm, greater than or about 4 μm, greater than or about 5 μm, greater than or about 6 μm, greater than or about 7 μm, greater than or about 8 μm, greater than or about 9 μm, greater than or about 10 μm, greater than or about 11 μm, greater than or about 12 μm, greater than or about 13 μm, greater than or about 14 μm, greater than or about 15 μm, greater than or about 16 μm, greater than or about 17 μm, greater than or about 18 μm, greater than or about 19 μm, or greater, and less than or about 20 μm.

In some embodiments, the UV blocking layer may have a thickness greater than or about 0.5 μm and less than or about 50 μm. The thickness of the UV blocking layer may be greater than or about 1 μm, greater than or about 5 μm, greater than or about 10 μm, greater than or about 15 μm, greater than or about 20 μm, greater than or about 25 μm, greater than or about 30 μm, greater than or about 35 μm, greater than or about 40 μm, greater than or about 45 μm, or greater, and less than or about 50 μm. In some embodiments, UV blocking layer may have a thickness less than or about 1 mm, less than or about 0.9 mm, less than or about 0.8 mm, less than or about 0.7 mm, less than or about 0.6 mm, less than or about 0.5 mm, less than or about 0.4 mm, less than or about 0.3 mm, less than or about 0.2 mm, less than or about 0.1 mm, or less.

In some embodiments, the color conversion layers 104 may have a thickness greater than or about 1 μm and less than or about 50 μm. The thickness of the color conversion layers 104 may be greater than or about 1 μm, greater than or about 5 μm, greater than or about 10 μm, greater than or about 15 μm, greater than or about 20 μm, greater than or about 25 μm, greater than or about 30 μm, greater than or about 35 μm, greater than or about 40 μm, greater than or about 45 μm, or greater, and less than or about 50 μm.

In some embodiments, the pixel structure 101 may include pixel isolation structures 106. While in FIGS. 1A-1B the pixel isolation structures 106 illustrated as three discrete elements orthogonal to the first substrate 110 and the second substrate 100, the pixel isolation structures 106 may include a continuous structure defining the sub-pixels 121 in three dimensions. For example, the pixel-defining structure may include a continuous array of rectangular cells, illustrated in the cross-section view of FIGS. 1A-1B, such that the constituent layers of the color conversion layers 104 form rectangular planar layers substantially parallel to the transparent first substrate 110. The pixel isolation structures 106 may extend proud of the first substrate 110, such that the first substrate 110 may be coupled with the second substrate 100 through the pixel isolation structures 106. In some embodiments, the pixel structure 101 may include additional pixel isolation structures, as when, for example, the pixel isolation structures are not continuous, but rather are formed from multiple discrete structures.

The pixel isolation structures 160 may be or include a black matrix material, where the term black matrix describes a material formulated from a photosensitive acrylic resin and color pigments, producing a structure characterized by low specular reflection over a broad wavelength range including, but not limited to, UV and visible wavelengths. In this way, the pixel isolation structures 106 may define the sub-pixels 121, may isolate the sub-pixels 121 from each other, and may improve the precision and accuracy of color reproduction of the pixel structure 101. In some embodiments, the pixel isolation structures 106 may include a reflective layer 108 over at least a portion of the surfaces facing the constituent layers of the sub-pixels 121 and the light sources 102. Advantageously, as the color conversion material may act as an isotropic emitter, the reflective layer 108 may further improve the efficiency of the pixel structure 101 by increasing the fraction of UV light reaching the color conversion layers 104 and the fraction of visible light emitted by the sub-pixels 121. The reflective layer 108 may be formed from any reflective material, such as a metal layer.

The description of the pixel structure 101 above may apply to any of the materials used in the pixel structures throughout this disclosure. For example, the following figures include different methods of fabricating and assembling a pixel structure, and each of these fabrication methods may use the materials, distances, etc., described above for the pixel structure 101 in FIGS. 1A-1B.

FIGS. 1A-1B illustrate only one method of manufacturing a pixel structure for a microLED array. Specifically, this pixel structure 101 may be formed in two parts. First, the light sources may be mounted to the second substrate 100. The pixel isolation structures 106 may then be formed around the light sources 102. The color conversion layers 104 may then be formed directly on top of the light sources 102. For example, after patterning the walls to form the pixel isolation structures 106 of a pixel isolation grid, the pixel isolation structures 106 may be coated with the reflective layer 108. The reflective layer may include a highly reflective material or metal, such as aluminum. The pixel isolation structures 106 may be coated with the reflective layer 108 and may form individual cells that encapsulate each of the subpixels 121. Each of the individual cells formed by the pixel isolation structures 106 may include one of the light sources 102.

In order to form the color conversion layers 104, each of the cells may be filled with color conversion materials that correspond to the color associated with each subpixel 121. For example, a first color conversion layer may be configured to produce a bluish color as described above. This first color conversion layer may be deposited (e.g., by printing) in each of the individual cells in a first portion of the light sources 102 that correspond to blue subpixels. The bluish color conversion layers may then be cured using the light from these corresponding blue subpixels. For example, the interconnect 101 may be used to activate the light sources of the blue subpixels, and the UV light emitted from the blue subpixels may cure the corresponding bluish color conversion layers in the blue subpixels. Afterward, any of this first color conversion layer that produces a bluish color may be rinsed or removed from any other areas in the pixel structure 101. For example, any of the bluish color conversion layer outside of the pixel cells formed by the pixel isolation structures 106 would not be cured by the light from the blue subpixels, and may therefore be easily removed. The same process may be carried out for a second color conversion layer that is formed over a second portion of the light sources corresponding to a reddish color, and then for a third color conversion layer that is formed over a third portion of the light sources corresponding to a greenish color, and so forth. This process self-aligns the color conversion film at the sub-pixel layer. Some embodiments may also include spare, substitute, or dummy subpixels that may be used as a replacement for defective pixels or may be left idle.

As illustrated in FIG. 1A, each of these structures may be formed on the second substrate 100 successively. Finally, the first substrate 110, which may include a protective layer of covered glass may be bonded on top of the pixel structure 101. For example, an adhesive layer 112 (e.g., glue) may be deposited on a bottom side of the first substrate 110, and the first substrate 110 may then be secured to the top of the pixel structure 101. The adhesive layer 112 may be transparent so as not to significantly interfere with the light emitted from the light sources 102. The final pixel structure 101 is illustrated in FIG. 1B.

This method of forming a pixel structure includes a number of advantages. For example, the color conversion layers 104 may be formed directly on top of the light sources 102. In contrast to other methods, the adhesive layer 112 is not between the light sources 102 and the color conversion layers 104. This results in less light scattering and a more predictable light output from the color conversion layers 104. This process also allows for the formation of the color conversion layers 104 using the self-aligned method described above that conveniently uses the UV light emitted from the light sources 102 to cure the corresponding color conversion layers 104.

However, this method illustrated in FIGS. 1A-1B also includes a number of disadvantages or technical challenges. For example, it is difficult or impossible to repair individual pixels during the manufacturing process. Pixels may be defective due to poor bonding, missing or inadequate quantum dots, and so forth. After the color conversion layers 104 are formed, it is impossible to test and/or replace defective light sources 102. Additionally, the fabrication processes used to form the pixel isolation structures 106 directly on the second substrate 100 may cause damage to the second substrate 100 and/or the light sources 102. For example, environmental conditions (e.g., temperatures, pressures, etc.) used to form the pixel isolation structures 106 may cause damage to the second substrate 100 and/or the light sources 102.

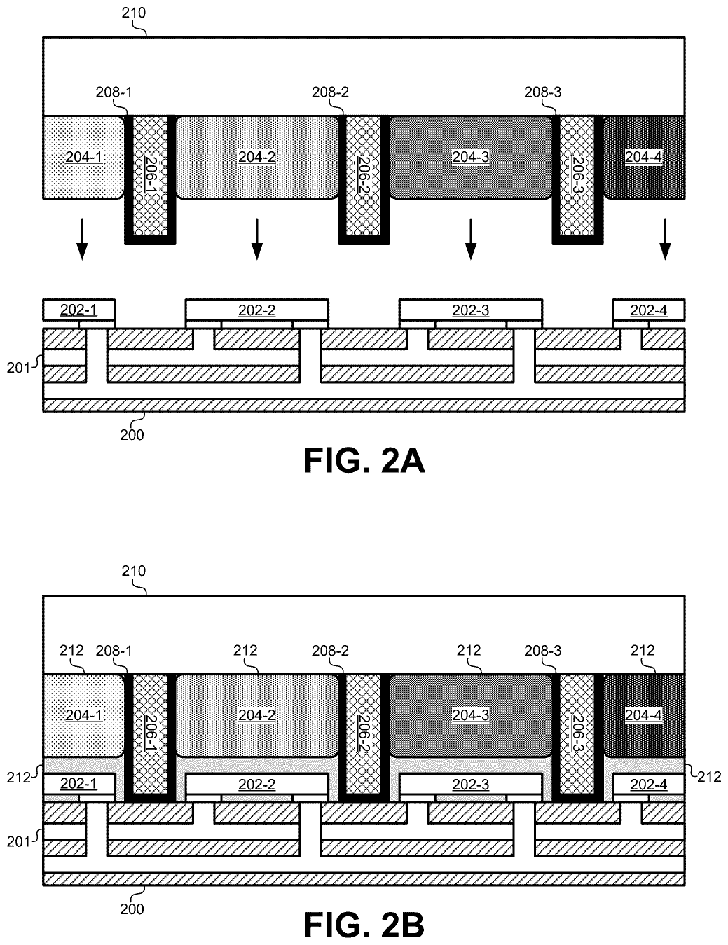

FIGS. 2A-2B illustrate an alternative method of fabricating a pixel structure 201, according to some embodiments. This pixel structure 201 may include elements that are the same or similar to the elements in the pixel structure 101 described above. For example, the pixel structure 201 may include a second substrate 200 with an interconnect 201 on which light sources 202 are mounted. A first substrate 210 may include a transparent substrate that serves as a protective cover glass. The pixel structure 201 may also include pixel isolation structures 206 with a reflective layer 208. The pixel isolation structures 206 may subdivide the pixel structure 201 into individual subpixels 221. Each of the individual subpixels 221 may include color conversion layers 204 corresponding to specific colors in the array.

In contrast to the assembly method illustrated in FIGS. 1A-2A, this assembly method alternatively forms the color conversion layers 204 and the pixel isolation structures 206 on the first substrate 210. The first substrate 210 may be transparent. For example, the grid formed by the pixel isolation structures 206 may be formed on the first substrate 210 without the light sources 202 yet therein. The pixel isolation structures 206 may then be coated with the reflective layer 208 to form the grid for the subpixels 221. These cells for the subpixels 221 may then be filled with the color conversion layers 204, and these color conversion layers 204 may then be cured.

The second substrate 200 may be formed to include the backplane with the interconnects 201. The light sources 202 may then be mounted to the second substrate 200. In order to join the two sections, an adhesive layer 212 may be applied over the color conversion layers 204, and the first substrate 210 may be attached to the second substrate 200 using the adhesive layer 212.

The second assembly method also provides a number of advantages. For example, the pixel isolation structures 260 may be formed separately from the more delicate electronics of the second substrate 200 and the light sources 202. However, this second assembly method does not allow for the self-aligned and self-curing procedure for forming the color conversion layers 204 described above. This second assembly method also places the adhesive layer 212 between the light sources 202 and the color conversion layers 204, which may interfere with the quality of the light emission.

The embodiments described herein solve these and other technical problems, while also maximizing the benefit of both of the assembly methods described above. This hybrid method of forming a microLED array may include forming pixel isolation structures on a sacrificial substrate while still mounting the microLEDs on the backplane. The processes that forms the pixel isolation structures, and which may damage the backplane or microLEDs can be separately performed on the sacrificial substrate. The pixel isolation structures can then be attached to the backplane and the sacrificial substrate can be removed. The color conversion layers may then be deposited individually and cured using the light from the corresponding microLEDs. A protective cover layer may then be adhered over the pixel isolation structures and the color conversion layers. This allows the formation of the pixel isolation structures to be isolated, the microLEDs to be tested prior to the color-conversion layer formation, the color conversion layers to be self-aligned and self cured, and the interface between the microLEDs and the color-conversion layers to be free of adhesive.

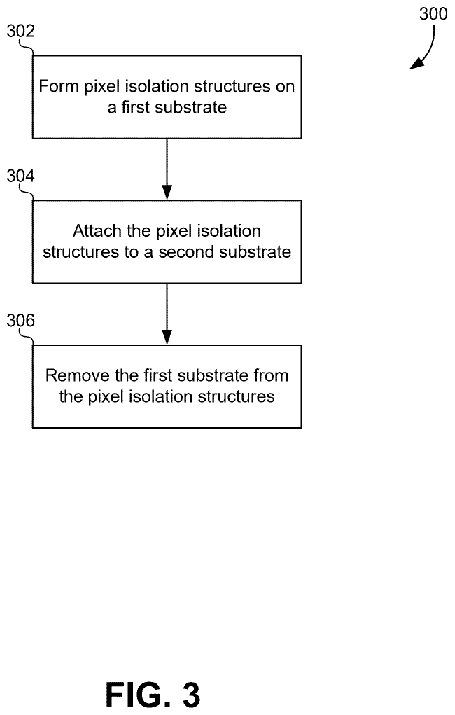

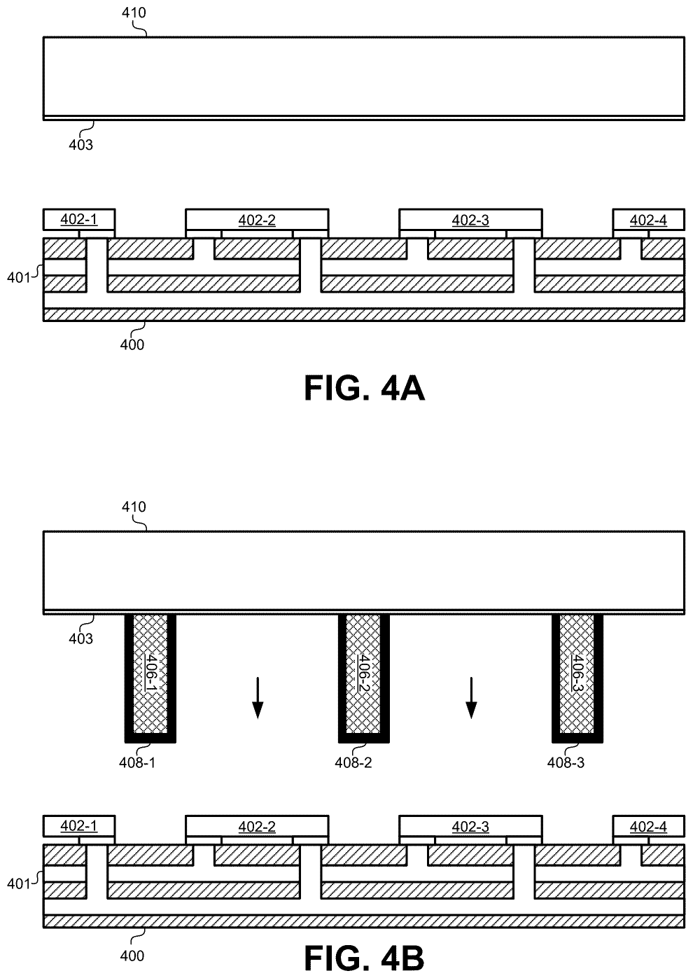

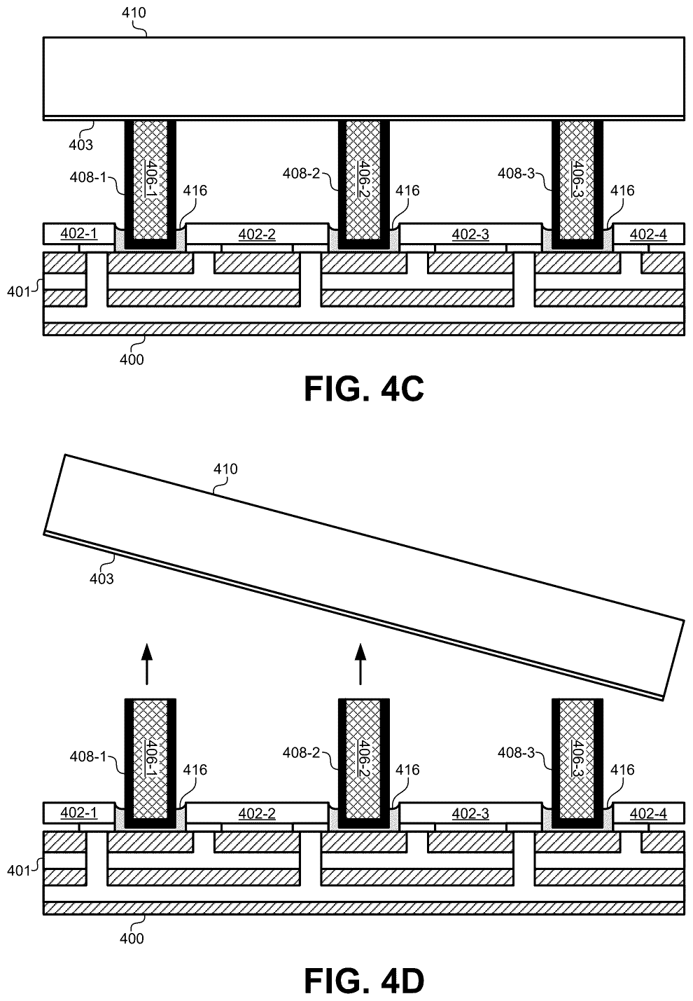

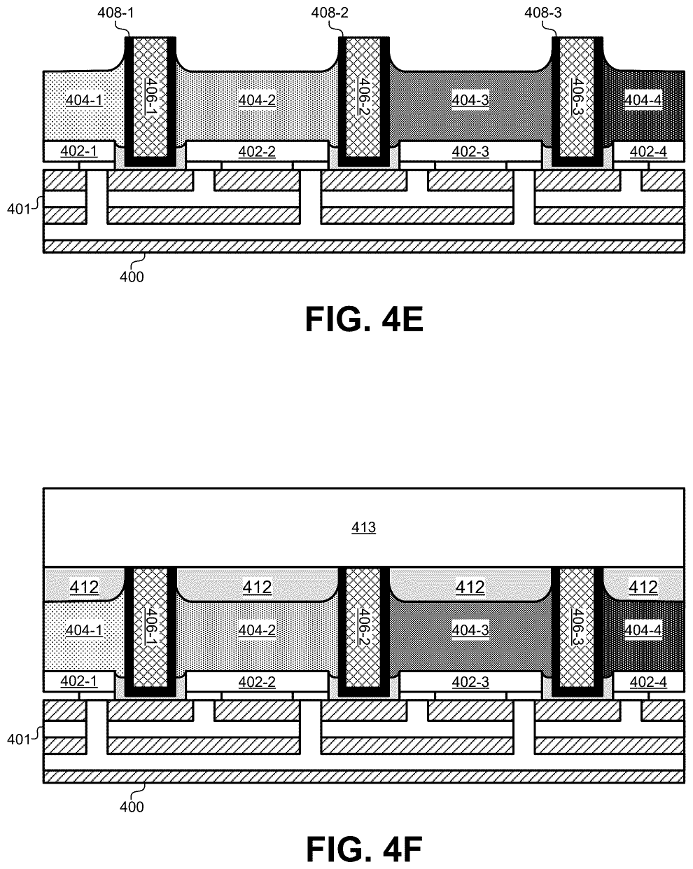

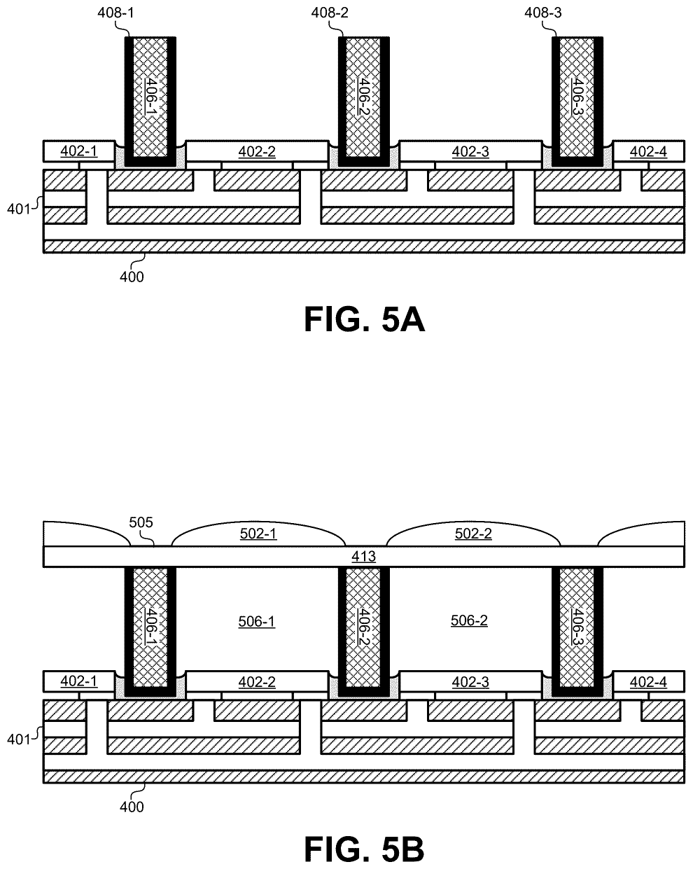

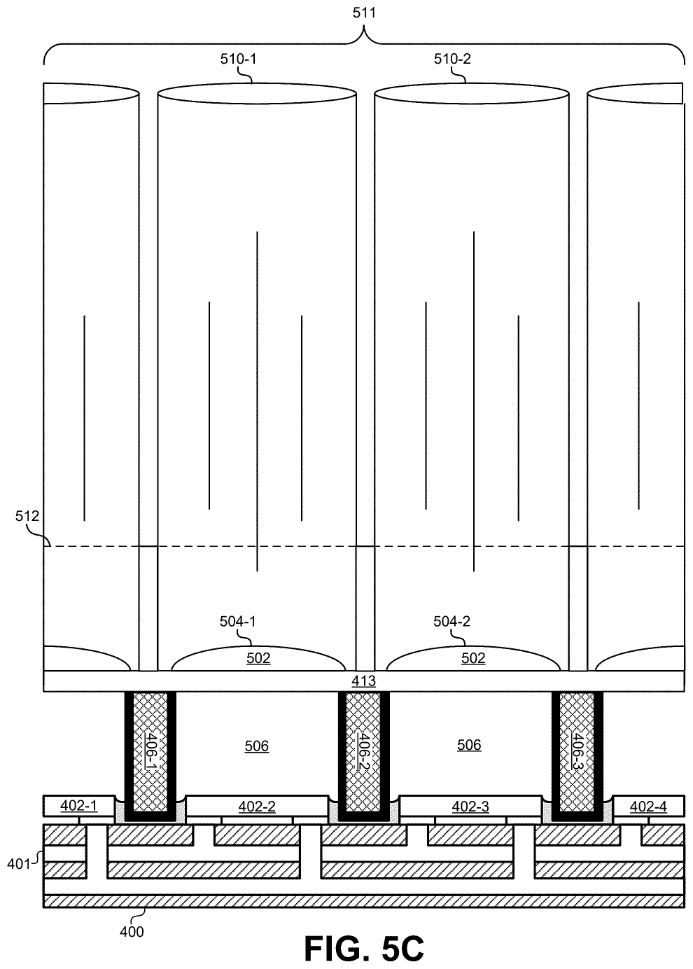

FIG. 3 illustrates a flowchart 300 of a method for forming pixel structures for microLED array, according to some embodiments. FIGS. 4A-4F illustrate example structures for some of the operations performed in the flowchart 300 for forming the microLED array for use in display applications. FIGS. 5A-5C illustrate example structures for some of the operations performed in the flowchart 300 for forming the microLED array for use in communication applications. The structures illustrated in these figures are provided only by way of example and are not meant to be limiting. Although discrete layers are illustrated, it should be understood that additional layers may be present that are not explicitly shown. These structures are not drawn to scale, but instead show relative sizes and a relative placement of materials and layers within the pixel structure 401. It should be appreciated that the specific steps illustrated in FIG. 3 provide particular methods of forming pixel structures according to various embodiments. Other sequences of steps may also be performed according to alternative embodiments. For example, alternative embodiments may perform the steps outlined above in a different order. Moreover, the individual steps illustrated in flowchart 300 may include multiple sub-steps that may be performed in various sequences as appropriate to the individual step. Furthermore, additional steps may be added or removed depending on the particular applications. Many variations, modifications, and alternatives also fall within the scope of this disclosure.

The method may include forming pixel isolation structures on a first substrate 410 (302). FIG. 4A illustrates a first substrate 410 on which the pixel isolation structures may be formed. The first substrate 410 may be flexible or rigid. Any type of material may be used to form the first substrate 410, including transparent and nontransparent materials. Since the pixel isolation structures need not be permanently affixed to the first substrate 410, the first substrate 410 may also be referred to as a “sacrificial” substrate. This also allows nontransparent materials to be used as the first substrate 410 that is not transparent with respect to light generated by the light sources.

In some embodiments, the first substrate 410 may be coated with an adhesive layer prior to forming the pixel isolation structures. For example, a surface of the first substrate 410 may be coated with a “first” adhesive layer 403 such that when the pixel isolation structures are later formed, the first adhesive layer 403 is between the pixel isolation structures and the first substrate 410. The first adhesive layer 403 may include a pressure-sensitive adhesive (PSA). For example, a PSA film comprising an organic-based material may be spread with uniform thickness on the first substrate 410. The first adhesive layer 403 may also have a melting point that may be lower than another adhesive used to secure the pixel isolation structures to a second substrate 400 as described below. A purpose of the first adhesive layer 403 may be to provide a way for the pixel isolation structures to be removed from the first substrate 410. For example, the first adhesive layer 403 may be formed from a thermal release film that may be sensitive to certain temperatures or certain specific light wavelengths. More generally, the first adhesive layer 403 may be responsive to a stimulus that causes the first adhesive layer 403 to be disrupted or otherwise released from the first substrate 410 and/or the pixel isolation structures.

A second substrate 400 may also be formed. The second substrate 400 may include a backplane with an interconnects 401 as described above. The light sources 402 may be separately formed and mounted to the second substrate 400.

FIG. 4B illustrates the formation of the pixel isolation structures 406 on the first substrate 410, according to some embodiments. The pixel isolation structures 406 may be formed as described in detail above. For example, the pixel isolation structures 406 may form an interconnected grid that is sized and spaced in order to later subdivide or isolate the light sources 402 from each other. In some embodiments, the pixel isolation structures 406 may be formed from high-aspect ratio photoresist material. The pixel isolation structures 406 may be formed by first patterning the first substrate 410 using photo-lithography, imprint-lithography, digital-lithography, and so forth. The resist material forming the pixel isolation structures 406 may then be spun onto the patterned first substrate 410 and the pattern for the pixel isolation structures may be removed. Additionally, a reflective layer 408 may be added to the pixel isolation structures 406. For example, a metallization of the walls of the pixel isolation structures 406 may be formed directly after patterning the resist for the pixel isolation structures 406 on the first substrate 410 using for example, oblique e-beam evaporation. These processes may be executed in a continuous process flow that is suitable for both flexible and rigid substrates (e.g., in a roll-to-roll process).

In contrast to the process described above in FIGS. 1A-1B, the pixel isolation structures 406 may be formed on the first substrate 410 that is physically separated from the second substrate 400 and the light sources 102. This provides a number of advantages when forming the pixel isolation structures. First, the light sources 402 may be protected from the processes used to form the pixel isolation structures 406 and/or the reflective layers 408. Additionally, when patterning the substrate to form the pixel isolation structures, the process may begin from the flat surface of the first substrate 410. If instead the pixel isolation structures 406 were formed on the second substrate 400, the patterned material would include undulations above the light sources 402 that can interfere with the precise formation of the pixel isolation structures 406.

The method of flowchart 300 may also include attaching the pixel isolation structures 406 to the second substrate 400 (304). As described above, the second substrate 400 may include the light sources 402 already mounted on the second substrate 400. Since a first, or top, side of the pixel isolation structures 406 may be secured to the first substrate 410, a second, or bottom, side of the pixel isolation structures 406 may be attached to the second substrate 400. The pixel isolation structures 406 may be attached such that the pixel isolation structures 406 isolate the light sources 402 from each other, such as in a grid or other regular geometric pattern. For example, the pixel isolation structures 406 may be attached such that the pixel isolation structures 406 contact the second substrate 400 in tracks or pathways that are arranged between the light sources 402.

The pixel isolation structures 406 may be attached to the second substrate 400 using a second adhesive layer 416. The second adhesive layer 416 may first be applied to the pixel isolation structures 406, and the pixel isolation structures 406 may then be brough into contact with the second substrate 400. This may prevent the second adhesive layer 416 from significantly covering the top or light-emitting portions of the light sources 402. Alternatively, the second adhesive layer 416 may be deposited directly in the spaces or pathways between the light sources 402 on the second substrate 400, and the first substrate 410 may be lowered onto the second substrate 400 such that the pixel isolation structures 406 contact the second adhesive layer 416 as illustrated in FIG. 4C.

The method of FIG. 300 may further include removing the first substrate 410 from the pixel isolation structures 406 (306). FIG. 4D illustrates the removal of the first substrate 410 from the pixel isolation structures 406, according to some embodiments. The removal of the first substrate 410 may include a number of different techniques. For example, a stimulus may be provided that causes the pixel isolation structures 406 to release from the first substrate 410. This stimulus may also be applied such that the pixel isolation structures 406 do not release from the second substrate 400. The first adhesive layer 403 may be released from the first side of the pixel isolation structures 406 that is adjacent to the first substrate 410, while the second adhesive layer 416 may remain intact on the second side of the pixel isolation structures 406 that is adjacent to the second substrate 400.

In one example, the first adhesive layer 403 may be particularly sensitive to a predetermined light wavelength. A laser ablation process may be used to either debond the first substrate 410 or detach the cured resist of the pixel isolation structures 406 at the interface of the first substrate 410. For example, a laser may be applied to the pixel structure 401 with a focal point of the laser focused directly on the interface between the pixel isolation structures 406 and the first substrate 410. This allows the laser to be focused directly at the depth of the first adhesive layer 403. A wavelength of the laser may be selected such that the laser causes the first adhesive layer 403 to break down and release the pixel isolation structures 406. When this laser is used as a stimulus, the second adhesive layer 416 may remain intact and continue to bond the pixel isolation structures 406 to the second substrate 400. In this case, the focal length of the laser may be set such that the laser ablation process takes place at the first side of the pixel isolation structures 406 and the first adhesive layer 403, while not being focused enough to ablate the second adhesive layer 416 at the second side of the pixel isolation structures 406. Alternatively, different adhesives may be used for the first adhesive layer 403 and the second adhesive layer 416. The first adhesive layer 403 may be sensitive to the wavelength of the laser, while the second adhesive layer 416 may not be sensitive to the wavelength of the laser.

In other embodiments, the first adhesive layer 403 may have a first melting point, and the second adhesive layer 416 may have a second melting point. The first melting point may be lower than the second melting point such that as the temperature is increased, the first adhesive layer 403 melts before the second adhesive layer 416. Thus a temperature stimulus may be provided to the pixel structure 401 such that the temperature stimulus is between the first and second melting points. The first substrate 410 may then be removed from the pixel isolation structures 406 when the first adhesive layer melts 403 without causing the second adhesive layer 416 to melt, and the second adhesive layer 416 may still hold the pixel isolation structures 406 to the second substrate 400.

At this stage, the pixel isolation structures 406 have been separately formed and properly aligned on the second substrate 400. This avoids the problems of forming the pixel isolation structures 406 that were described above. This also allows for the inspection or test of the light sources 402 before adding the color conversion layers. For example, the inspection or test of the light sources 402 may identify defective subpixels. Light sources 402 from individual subpixels may be removed and/or replaced from the first substrate 400 before adding the color conversion layers.

FIG. 4E illustrates the formation of the color conversion layers 404, according to some embodiments. Since the pixel isolation structures 406 are already in place, the color conversion layers 404 may be formed using the self-aligned, self-curing procedure described above. For example, individual colors of the color conversion layers 404 may be placed in the corresponding subpixel grid areas directly on top of the light sources 402 (i.e., without an adhesive layer between the color conversion layers 404 and the light sources 402). The light sources 402 may then be activated to cure the color conversion layers 404. Any residual material from the color conversion layers 404 that are not above activated light sources (and therefore remain uncured) may be rinsed or removed before moving to the next color.

FIG. 4F illustrates the pixel structure 401 with a protective substrate 413 applied, according to some embodiments. The protective substrate 413 may include a cover or glass cover that protects the pixel structure 401. The protective substrate 413 may include a transparent substrate that allows light to be emitted from the light sources 402. A cover adhesive 412 may be used to attach the protective substrate 413 to the pixel structure 401. Note that the cover adhesive 412 does not interfere with the interface between the color conversion layers 404 and the light sources 402.

The pixel structure 401 may be distinguished from the pixel structure 101 from FIGS. 1A-1B and the pixel structure 201 from FIGS. 2A-2B by virtue of the process by which these pixel structures are formed. However, the pixel structure 401 may also be distinguished based on structural differences. For example, the pixel structure 401 may include an adhesive layer that connects the pixel isolation structures 406 to the first substrate 401. In this final pixel structure 401, this adhesive layer may be referred to as a “first” adhesive layer to distinguish it from a “second” adhesive layer formed by the cover adhesive 412. Additionally, the pixel structure 401 may include the reflective layer 408 that covers the bottom side of the pixel isolation structures 406 that is connected to the first substrate 400, while not covering the top side of the pixel isolation structures 406 that is connected to the protective substrate 413.

The hybrid process for forming pixel isolation structures described herein may be utilized in applications beyond color-conversion-based display technologies. For example, the process may also be compatible with the fabrication of microLED arrays configured for use in communication systems, wherein the microLEDs transmit data rather than emit visible light for display purposes. In embodiments utilizing microLED communication systems, the pixel isolation structures may be formed on a sacrificial substrate and attached to the backplane as described above. These pixel isolation structures may isolate light emitted by individual microLEDs and facilitate precise alignment of the light sources with corresponding optical components, such as a fiber-optic bundle.

For example, the fabrication processes used to form the pixel isolation structures, including patterning, deposition, and metallization, may be performed on a sacrificial substrate, thereby protecting the microLEDs and backplane from adverse environmental conditions such as high temperatures or pressures as described above. Since the microLEDs are used for communication, pixel redundancies may not be as readily used for remedying defective pixels. Instead, the microLEDs may be inspected and tested for functionality prior to the attachment of the pixel isolation structures. This allows defective microLEDs to be identified and replaced before further assembly steps are performed. The pixel isolation structures may also be attached to the backplane in a manner that precisely aligns the microLEDs with external optical components. For example, the pixel isolation structures may assist in directing light emitted by the microLEDs into individual fibers within a fiber-optic bundle, thereby improving the efficiency and accuracy of optical signal transmission. In this way, the hybrid process described herein provides a versatile solution for fabricating microLED arrays and enabling their use in applications such as communication systems that do not necessarily require color-conversion layers. This compatibility expands the scope of the process beyond traditional display applications and provides additional technical advantages for emerging optical communication technologies.

MicroLED communication systems may use microLEDs mounted on an LED substrate to transmit optical signals for data communication purposes. In such systems, individual microLEDs may emit light configured to represent binary data, where the activation and deactivation of the microLEDs correspond to binary “1” and “0” values. The light emitted by the microLEDs may be coupled into a fiber-optic bundle aligned with the microLED array. Each fiber within the bundle may correspond to a specific microLED or group of microLEDs, and may carry the optical signal to a receiving system, die, or chip. The photodetectors on the receiving system may be configured to detect the light signals transmitted through the fiber-optic bundle and convert them into electrical signals for further processing.

This configuration allows for high-speed, high-bandwidth optical communication by leveraging the fast response times and high efficiency of microLEDs. The precise alignment of the microLEDs with the fiber-optic bundle ensures minimal signal loss and high fidelity of the transmitted data. Such microLED communication systems may be utilized in applications requiring rapid data transfer between electronic systems, including inter-chip communication, high-performance computing systems, and optical interconnects. The use of pixel isolation structures formed by the hybrid process described herein enhances the performance of microLED communication systems by isolating the light sources and facilitating precise alignment between the microLEDs and the fiber-optic bundle. This improves the accuracy and efficiency of data transmission, further expanding the applicability of microLED arrays in advanced communication technologies.

FIG. 5A illustrates the resulting structure after removing the first substrate 410, as described in FIG. 4D. However, in contrast to the structure shown in FIG. 4E, this structure may be configured for microLED communication rather than for display purposes. As shown, the pixel isolation structures 406 are bonded now to the second substrate 400, which serves as the backplane (or the LED substrate) for the light sources 402. In microLED applications, no color-conversion layer is necessarily added to the spaces or wells formed by the pixel isolation structures 406. Instead, the light sources 402 emit light directly into external optical components, such as a fiber-optic bundle as described below, for communication purposes.

The light sources 402 may emit light across a broad range of wavelengths, which is not limited to the visible light wavelengths typically used in display applications. For example, the light sources 402 may emit in the ultraviolet (UV) range, such as UV-A (315-400 nm), UV-B (280-315 nm), or UV-C (100-280 nm). Additionally, the light sources 402 may emit visible light wavelengths, such as blue (380-500 nm), green (500-570 nm), or red (620-750 nm), as well as infrared (IR) wavelengths, such as near-infrared (700-1400 nm). In microLED communication systems, the broader range of wavelengths-including UV and IR-offers advantages, such as higher modulation speeds, enhanced optical coupling efficiency into fiber-optic systems, and compatibility with specialized photodetectors for data transmission. Therefore, different embodiments may use different wavelength ranges depending on the requirements of the application. The flexibility in wavelength selection allows microLED communication systems to be tailored for diverse applications, including high-speed data transfer, inter-chip communication, and optical interconnects.

The pixel isolation structures 406 may include the reflective layer 408 formed on the surfaces facing the light sources 402 and the spaces or wells between them as described in detail above. The reflective layer 408 serves several functions in microLED communication systems. First, it channels light emitted by the light sources 402 directly upwards, ensuring that the light is efficiently directed into the fiber-optic bundle or other optical components. Second, the reflective layer 408 prevents any crosstalk or light bleeding between adjacent wells or LED areas. This isolation ensures that each light source 402 transmits its signal independently, maintaining the integrity of the optical signals and preventing false signals or interference in adjacent channels.

Crosstalk prevention is particularly important in microLED communication systems, where high-density arrays of microLEDs are used to transmit binary signals through light. Any unintended transmission of light between adjacent LED areas could result in errors in the transmitted data, degrading the performance and reliability of the communication system. The reflective layer 408 mitigates these risks, ensuring that each microLED emits light exclusively into its designated channel, thereby improving signal fidelity and transmission efficiency.

FIG. 5B illustrates a structure with optional optical components positioned above the light sources 402, according to some embodiments. In some applications, the structure may include intermediate layers or spacers to enhance the performance and functionality of the microLED communication system. These optional intermediate layers may include materials such as glass, polymers, or thin-film coatings designed to protect the microLEDs, improve light coupling efficiency, or serve as spacers to ensure precise alignment between the microLEDs and the corresponding optical components, such as fibers in a fiber-optic bundle. For example, clear film materials that readily transmit light may be used to fill the wells 506 between the pixel isolation structures or may be placed on top of the pixel isolation structures. These layers can act as optical interfaces to reduce light scattering and improve the directionality of emitted light, ensuring that light is efficiently transmitted into the fiber-optic bundle. Additionally, these intermediate layers may provide mechanical protection for the microLEDs and maintain structural integrity during assembly and operation.

In some embodiments, micro-lenses 502 may optionally be added above each of the light sources 402 within the wells formed by the pixel isolation structures 406. These micro-lenses 502 may be positioned directly above the light-emitting surface of each light source and designed to focus the emitted light into the corresponding optical fibers of the attached fiber-optic bundle. By concentrating and directing the light output, the micro-lenses 502 may enhance the optical coupling efficiency, ensuring that a greater proportion of the light emitted by each microLED is transmitted into the individual optical fibers. This reduces optical losses, improves signal strength, and increases the overall data transmission efficiency of the system. Additionally, the use of micro-lenses minimizes the divergence of the light beam, which helps maintain signal fidelity and reduces the risk of crosstalk or interference between adjacent optical channels.

FIG. 5C illustrates a fiber-optic bundle 511 coupled to the microLED array, according to some embodiments. The fiber-optic bundle 511 may include a plurality of individual optical fibers 510 packaged together to facilitate efficient coupling with the microLED array. Each optical fiber 510 may correspond to a specific light source 402 and/or micro-lens 502. The coupling between the microLED array and the fiber-optic bundle 511 may be achieved through precise alignment techniques, wherein the light emitted by each microLED is focused directly into the corresponding optical fiber 510. For example, the micro-lenses 502 positioned above the light sources 402 may focus the emitted light into the fiber cores, ensuring minimal optical losses and maximum signal fidelity during transmission.

An optional ferrule 512 may be used to hold the optical fibers 510 together in a fixed arrangement, aligning them automatically with the pixel isolation structures 406 during assembly. The ferrule 512 may include features that match the geometry of the pixel isolation structures, ensuring that the optical fibers 510 align precisely with the wells formed by the pixel isolation structures and the corresponding light sources 402. This automatic alignment simplifies the assembly process and ensures efficient coupling of light into the optical fibers, while also minimizing the risk of crosstalk or interference between adjacent fibers.

It should be appreciated that the configuration shown in FIG. 5C is only one example and is not meant to be limiting. Other embodiments may employ alternative methods for coupling the optical fibers 510 to the microLED array. For instance, optical fibers may be inserted directly into the wells formed by the pixel isolation structures 406, eliminating the need for micro-lenses or ferrules. Additional lenses, spacers, or coupling components may also be included to further reduce crosstalk and ensure that light emitted by the microLEDs is directed maximally into the optical fibers 510. These variations may be tailored to specific application requirements, enabling the system to optimize performance based on factors such as signal fidelity, bandwidth, and manufacturing constraints.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming pixel structures for a microLED array, the method comprising:
forming pixel isolation structures on a first substrate;
attaching the pixel isolation structures to a second substrate, wherein the second substrate comprises light sources, and the pixel isolation structures isolate the light sources from each other; and
removing the first substrate from the pixel isolation structures.

2. The method of claim 1, further comprising performing an inspection or test of the light sources after attaching the pixel isolation structures to the second substrate and before forming additional layers over the light sources.

3. The method of claim 2, further comprising replacing a defective light source on the second substrate as a result of the inspection or test and before forming the color-conversion layer over the light sources.

4. The method of claim 1, further comprising:
forming a first color-conversion layer within first regions formed by the pixel isolation structures and over a first portion of the light sources, wherein the first color-conversion layer comprises a bluish color;
curing the first color-conversion layer within the first regions using light from the first portion of the light sources; and
removing any of the first color-conversion layer outside of the first regions after curing.

5. The method of claim 4, further comprising:
forming a second color-conversion layer within second regions formed by the pixel isolation structures over a second portion of the light sources, wherein the second color-conversion layer comprises a reddish color;
curing the second color-conversion layer within the second regions using light from the second portion of the light sources; and
removing any of the second color-conversion layer outside of the second regions formed by the pixel isolation structures after curing.

6. The method of claim 5, further comprising:
forming a third color-conversion layer within third regions formed by the pixel isolation structures over a third portion of the light sources, wherein the third color-conversion layer comprises a reddish color;
curing the third color-conversion layer within the third regions using light from the third portion of the light sources; and
removing any of the third color-conversion layer outside of the third regions formed by the pixel isolation structures after curing.

7. The method of claim 1, further comprising attaching a transparent substrate to the pixel isolation structures in place of the first substrate after the first substrate is removed.

8. A method of forming pixel structures for a microLED array, the method comprising:
forming pixel isolation structures on a first substrate;
attaching the pixel isolation structures to a second substrate such that the first substrate is attached to a first side of the pixel isolation structures, and the second substrate is attached to a second side of the pixel isolation structures; and
providing a stimulus that causes the pixel isolation structures to release from the first substrate without causing the pixel isolation structures to release from the second substrate.

9. The method of claim 8, wherein light sources are mounted to the second substrate and connected by an interconnect of the second substrate, and the first substrate comprises a sacrificial substrate that is nontransparent with respect to light generated by the light sources mounted to the second substrate.

10. The method of claim 8, further comprising coating a surface of the first substrate with a first adhesive layer prior to forming the pixel isolation structures on the first substrate, wherein the pixel isolation structures are formed such that the first adhesive layer is between the surface of the first substrate and the first side of the pixel isolation structures.

11. The method of claim 10, wherein the first adhesive layer comprises a pressure-sensitive adhesive.

12. The method of claim 10, wherein the second side of the pixel isolation structures are attached to the second substrate using a second adhesive layer.

13. The method of claim 12, wherein the stimulus comprises a laser, and the laser is provided with a focal length that focuses at the first adhesive layer and that does not focus at second adhesive layer.

14. The method of claim 12, wherein the stimulus comprises a laser that emits light at a wavelength, and the wavelength disrupts the first adhesive layer without disrupting the second adhesive layer.

15. The method of claim 12, wherein the first adhesive layer has a melting point that is lower than the second adhesive layer.

16. The method of claim 15, the stimulus comprises a temperature that causes the first adhesive layer to melt without causing the second adhesive layer to melt.

17. A pixel structure of a display, the pixel structure comprising:
a substrate comprising light sources mounted to the substrate;
pixel isolation structures that isolate the light sources from each other, and that are connected to the substrate with a first adhesive layer; and
a transparent substrate disposed over the pixel isolation structures and connected to the pixel isolation structures with a second adhesive layer.

18. The pixel structure of claim 17, further comprising a reflective layer that covers sidewalls of the pixel isolation structures, wherein the reflective layer does not cover a first side of the pixel isolation structures that is connected to the transparent substrate.

19. The pixel structure of claim 17, further comprising a reflective layer that covers sidewalls of the pixel isolation structures, wherein the reflective layer also covers a first side of the pixel isolation structures that is connected to the substrate.

20. The pixel structure of claim 17, further comprising a reflective layer that comprises a metal material.
